(19) United States
(12) Patent Application Publication
(10) Pub. No.: US 2025/0351289 A1
(43) Pub. Date: Nov. 13, 2025

(54) FLOATING FASTENER MECHANISM AND COMPUTER CHASSIS HAVING THE SAME

(71) Applicant: Jabil Circuit (Singapore) Pte. Ltd., Singapore (SG)

(72) Inventors: Chen-Lu Fan, Taichung City (TW); Yu-Ming Lin, Taichung City (TW); Kuo-Jui Mei, Taichung City (TW)

(73) Assignee: Jabil Circuit (Singapore) Pte. Ltd., Singapore (SG)

(21) Appl. No.: 19/199,678

(22) Filed: May 6, 2025

(30) Foreign Application Priority Data
May 10, 2024 (CN) 202421009698.9

(51) Int. Cl. H05K 7/14

(52) U.S. Cl. CPC H05K 7/1489

(57) ABSTRACT

A floating fastener mechanism is adapted to be disposed on a chassis unit of a computer chassis, and is adapted to fasten an electronic component. The floating fastener mechanism includes a floating fastener and a limit member. The floating fastener has a floating bracket that is adapted to be disposed on the chassis unit and that is operable to move relative to the chassis unit in a predetermined direction, and an internal thread that is disposed on the floating bracket and that is adapted for an external thread member of the electronic component to threadedly engage therewith. The limit member is adapted for limiting movement of the floating bracket relative to the chassis unit.

### CROSS-REFERENCE TO RELATED APPLICATION

This application claims priority to Chinese Utility Model patent application Ser. No. 202421009698.9, filed on May 10, 2024, the entire disclosure of which is incorporated by reference herein.

### FIELD

The disclosure relates to a floating fastener mechanism, and more particularly to a floating fastener mechanism adapted to fasten an electronic component, and a computer chassis having the floating fastener mechanism.

### BACKGROUND

In order to conform to new standards of form factors, a computer chassis of a conventional server has to allow an electronic component to be mounted to a motherboard that may come in any one of specifications. However, because a connector that is disposed on the motherboard may be changed accordingly and the height of an electronic component that is inserted to the connector may be offset accordingly when the thickness of a motherboard is varied, the computer chassis may not be able to stably fasten the electronic component to the motherboard through the connector.

### SUMMARY

Therefore, an object of the disclosure is to provide a floating fastener mechanism that can alleviate the drawback of the prior art.

According to the disclosure, the floating fastener mechanism is adapted to be disposed on a chassis unit of a computer chassis, and is adapted to fasten an electronic component. The floating fastener mechanism includes a floating fastener and a limit member. The floating fastener has a floating bracket that is adapted to be disposed on the chassis unit and that is operable to move relative to the chassis unit in a predetermined direction, and an internal thread that is disposed on the floating bracket and that is adapted for an external thread member of the electronic component to threadedly engage therewith. The limit member is adapted for limiting movement of the floating bracket relative to the chassis unit.

Another object of the disclosure is to provide a computer chassis that can alleviate the drawback of the prior art.

According to the disclosure, the computer chassis is adapted for an electronic component to be inserted thereto. The computer chassis includes the floating fastener mechanism as mentioned above, and a chassis unit. The chassis unit is formed with an elongated hole that is elongated in a predetermined direction, that corresponds in position to the internal thread of the floating fastener of the floating fastener mechanism, and that is adapted for an external thread member of the electronic component to extend therethrough to threadedly engage the internal thread.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a fragmentary perspective view of a first embodiment of a computer chassis according to the disclosure, illustrating the computer chassis being disposed on an electronic device.

FIG. 2 is a fragmentary, partly exploded perspective view illustrating how the first embodiment and an electronic component of the electronic device are assembled.

FIG. 3 is a fragmentary rear view of part of the first embodiment, illustrating a floating fastener of a floating fastener mechanism of the first embodiment being in an initial position.

FIG. 4 is a fragmentary, sectional front view of part of the first embodiment, illustrating the floating fastener being in the initial position.

FIG. 5 is a sectional view taken along line V-V in FIG. 3.

FIG. 6 is a fragmentary, partly exploded perspective view of part of the first embodiment, illustrating how the floating fastener mechanism and a chassis unit of the first embodiment are assembled.

FIG. 7 is a fragmentary, schematic exploded perspective view of part of the first embodiment, illustrating the floating fastener mechanism and the chassis unit from another viewing angle.

FIG. 8 is a perspective view illustrating that the floating fastener and a resilient member of the floating fastener mechanism of the first embodiment are being assembled.

FIG. 9 is a front view of an assembly of the floating fastener and the resilient member.

FIG. 10 is a fragmentary sectional view taken along line X-X in FIG. 1.

FIG. 11 is a fragmentary rear view of part of the first embodiment, illustrating the floating fastener being in a first floated position.

FIG. 12 is a fragmentary, sectional front view of part of the first embodiment, illustrating the floating fastener being in the first floated position.

FIG. 13 is a fragmentary rear view of part of the first embodiment, illustrating the floating fastener being in a second floated position.

FIG. 14 is a fragmentary, sectional front view of part of the first embodiment, illustrating the floating fastener being in the second floated position.

FIG. 15 is a fragmentary, sectional front view of part of a second embodiment of the computer chassis according to the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

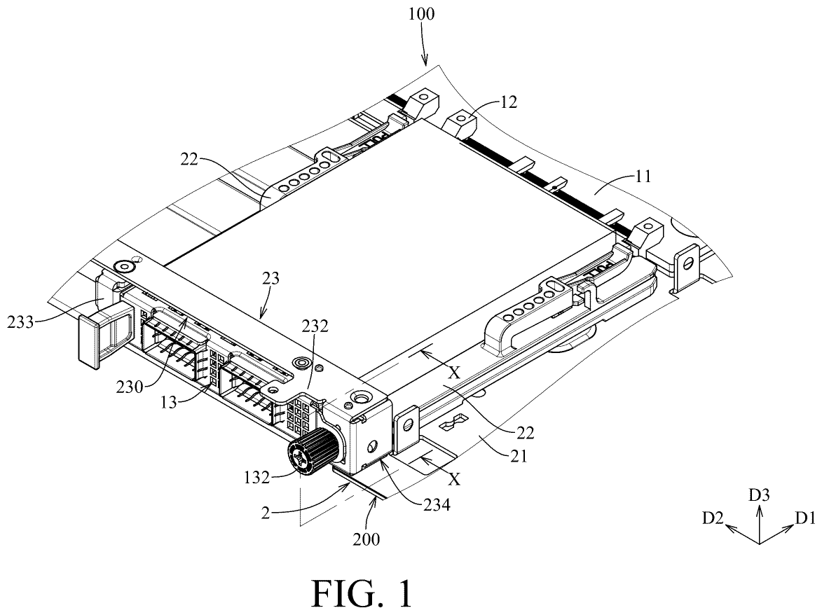

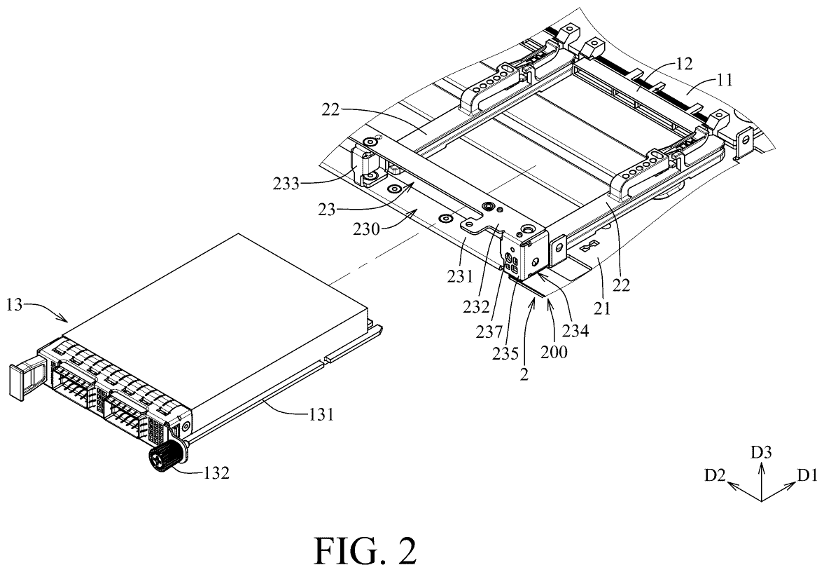

Referring to FIGS. 1 and 2, a first embodiment of a computer chassis 200 according to the disclosure is adapted to be disposed on an electronic device 100. In this embodiment, the electronic device 100 is exemplified as a server. However, in certain embodiments, the electronic device 100 may be, but not limited to be, a computer or a storage device. The electronic device 100 includes a motherboard 11, a connector 12, and an electronic component 13. The motherboard 11 is disposed in the computer chassis 200. The connector 12 is disposed on the motherboard 11 and is electrically coupled to the motherboard 11. The computer chassis 200 is adapted for the electronic component 13 to be inserted thereto so that the electronic component 13 is inserted to the connector 12 via the computer chassis 200. The electronic component 13 may be an Open Compute Project (OCP) card module, or a Datacenter-ready Secure Control Module (DC-SCM). In the first embodiment, the electronic component 13 is exemplified as an OCP card module. The electronic component 13 includes an electronic card 131 and an external thread member 132. The electronic card 131 is used for inserting the connector 12. The external thread member 132 may be, but not limited to be, a thumb screw.

It is noted that, for explanatory convenience, a predetermined direction (D3), a first transverse direction (D1), and a second transverse direction (D2) of the computer chassis 200 are defined respectively to be an up-down direction, a front-rear direction, and a left-right direction of the computer chassis 200. The first transverse direction (D1) is transverse to the predetermined direction (D3). The second transverse direction (D2) is transverse to the predetermined direction (D3) and the first transverse direction (D1). Referring to FIG. 1, an arrow that points up represents the predetermined direction (D3), an arrow that points to the front represents the first transverse direction (D1), and an arrow that points to the left represents the second transverse direction (D2).

Referring to FIGS. 2 to 5, the computer chassis 200 includes a chassis unit 2 and a floating fastener mechanism 3. The chassis unit 2 includes a base plate 21, two guide rails 22, and a frame 23. The base plate 21 is adapted for the motherboard 11 to be disposed thereon. The guide rails 22 are disposed on the base plate 21, are spaced apart from each other in the second transverse direction (D2), and are respectively located at left and right sides of the connector 12. The guide rails 22 are adapted for guiding the electronic component 13 to move along the first transverse direction (D1) so that the electronic card 131 of the electronic component 13 may be inserted to the connector 12. The frame 23 is disposed on the base plate 21 and is located at a rear of the guide rails 22. The frame 23 has a base wall 231, a top wall 232, a lateral frame body 233, and a lateral frame body 234. The base wall 231 is disposed on the base plate 21. The top wall 232 is spaced apart from the base wall 231 in the predetermined direction (D3) and is located above the base wall 231. Each of the lateral frame body 233 and the lateral frame body 234 interconnects the base wall 231 and the top wall 232. The lateral frame body 233 and the lateral frame body 234 are spaced apart from each other in the second transverse direction (D2). The base wall 231, the top wall 232, and the lateral frame bodies 233, 234 cooperatively define an insertion opening 230. The lateral frame body 234 has a rear wall 235 that interconnects the base wall 231 and the top wall 232, and two lateral walls 236 that extend forwardly and respectively from left and right sides of the rear wall 235. The rear wall 235 is formed with an elongated hole 237, an open hole 238, and a plurality of vent holes 239. The elongated hole 237 is elongated in the predetermined direction (D3), and is adapted for the external thread member 132 of the electronic component 13 to extend therethrough. The open hole 238 is spaced apart from the elongated hole 237 in the predetermined direction (D3), and is located above the elongated hole 237. The vent holes 239 are spaced apart from the elongated hole 237, and at least partially surround the elongated hole 237. It is noted that, in some embodiments, the number of the vent hole(s) 239 may be one.

The floating fastener mechanism 3 is disposed on the chassis unit 2, and is adapted to fasten the electronic component 13. The floating fastener mechanism 3 includes a floating fastener 4, a limit member 5, and a resilient member 6. The floating fastener 4 may be made of, for example, a metal material, and be formed by a stamping process and a bending process. The floating fastener 4 has a floating bracket 41, and an internal thread 42 that is disposed on the floating bracket 41. The floating bracket 41 is disposed in the lateral frame body 234 of the frame 23 of the chassis unit 2, and is operable to move relative to the chassis unit 2 in the predetermined direction (D3). The floating bracket 41 abuts against a front surface of the rear wall 235. The internal thread 42 corresponds in position to the elongated hole 237 of the lateral frame body 234, and is adapted for the external thread member 132 of the electronic component 13 to threadedly engage therewith so that the electronic component 13 may be fixedly secured to the floating fastener 4. The external thread member 132 extends through the elongated hole 237 to threadedly engage with the internal thread 42. The limit member 5 limits movement of the floating bracket 41 relative to the rear wall 235 of the lateral frame body 234 of the chassis unit 2. By virtue of the floating bracket 41 being operable to move relative to the chassis unit 2 in the predetermined direction (D3), the internal thread 42 is floatable relative to the chassis unit 2, thereby allowing the floating fastener mechanism 3 to stably fasten the electronic component 13 to a motherboard that is disposed on the chassis unit 2 and that has a thickness different from the abovementioned motherboard 11 even when a height of the electronic component 13 is offset due to the different thickness of the motherboard.

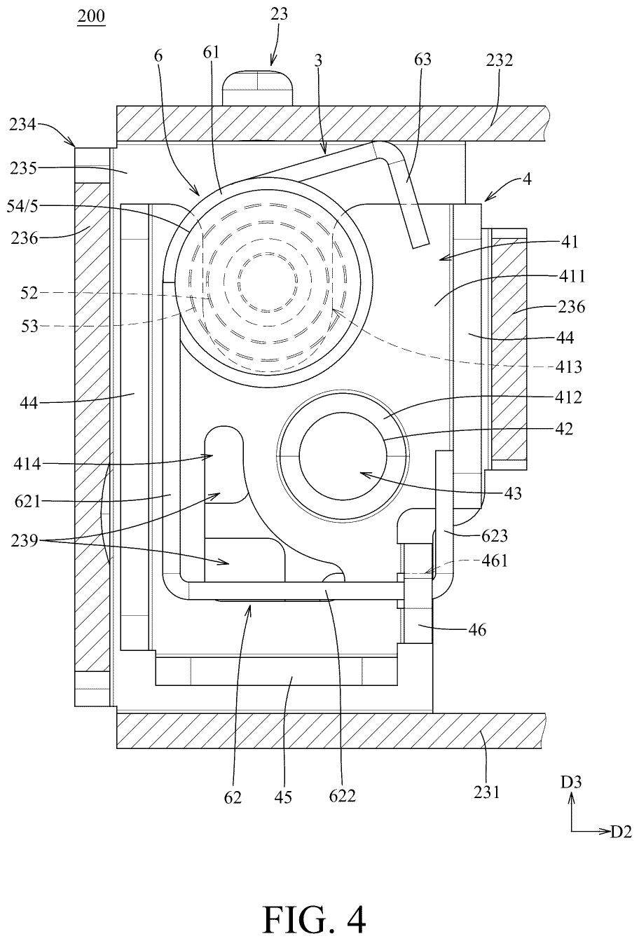

Referring to FIGS. 4 to 7, the floating bracket 41 has a main plate 411, and an annular protrusion 412 that protrudes from a front surface of the main plate 411. The main plate 411 abuts against the front surface of the rear wall 235. The internal thread 42 is formed on the main plate 411 and the annular protrusion 412, and cooperates with the main plate 411 and the annular protrusion 412 to define a threaded hole 43. The threaded hole 43 is adapted for the external thread member 132 of the electronic component 13 (see FIG. 2) to insert therein. By virtue of the internal thread 42 being formed on the main plate 411 and the annular protrusion 412, a depth of each of the internal thread 42 and the threaded hole 43 may be relatively great in the first transverse direction (D1). Therefore, a screw-in depth of the external thread member 132 in the internal thread 42 may be relatively great, thereby increasing stability of a threaded engagement between the external thread member 132 and the internal thread 42.

A top end of the main plate 411 of the floating bracket 41 is recessed downwardly to form a floating groove 413. The floating groove 413 is elongated in the predetermined direction (D3). The limit member 5 extends through the floating groove 413 and movably engages the floating groove 413 so that the floating groove 413 is movable relative to the chassis unit 2 in the predetermined direction (D3). The limit member 5 blocks the main plate 411 of the floating bracket 41 so that the floating bracket 41 is prevented from being separated from the chassis unit 2.

The main plate 411 of the floating bracket 41 is formed with a vent hole 414. The vent hole 414 is adjacent to a bottom end of the main plate 411, corresponds in position to the vent holes 239, and spatially communicates with the vent holes 239. By virtue of the vent hole 414 corresponding in position to the vent holes 239 and spatially communicating with the vent holes 239, an air exhaust capacity of the computer chassis 200 (i.e., the amount of air that flows from the computer chassis 200 to an external environment through the vent hole 414 and the vent holes 239) may be increased, thereby enhancing heat dissipation of the computer chassis 200 (see FIG. 2).

The floating fastener 4 further has two lateral plates 44, an end plate 45, and a connection plate 46. The lateral plates 44 are respectively connected to left and right sides of the main plate 411 of the floating bracket 41, and are spaced apart from each other in the second transverse direction (D2). In this embodiment, each of the lateral plates 44 extends forwardly from the main plate 411, is configured to be an elongated plate, and is elongated in the predetermined direction (D3). The lateral plates 44 are located between the lateral walls 236, and are respectively blocked by the lateral walls 236 in the second transverse direction (D2). By virtue of the lateral walls 236 of the lateral frame body 234 respectively blocking the lateral plates 44 in the second transverse direction (D2), the floating fastener 4 is prevented from rattling in the second transverse direction (D2), and from rotating relative to the limit member 5. The end plate 45 is connected to the bottom end of the main plate 411, and extends forwardly from the bottom end of the main plate 411. The end plate 45 cooperates with the lateral plates 44 to improve an overall structural strength of the floating fastener 4. The connection plate 46 is connected to one side of the main plate 411 of the floating bracket 41, extends forwardly from the main plate 411, and is adjacent to the end plate 45. The lateral plates 44 are located at two opposite sides of the connection plate 46 in the second transverse direction (D2). The connection plate 46 is formed with a through hole 461. It is noted that, in this embodiment, the main plate 411, the lateral plates 44, the end plate 45, and the connection plate 46 are integrally formed as one piece, and the lateral plates 44, the end plate 45, and the connection plate 46 are formed by the bending process (i.e., the lateral plates 44, the end plate 45, and the connection plate 46 are bent relative to the main plate 411). However, in some embodiments, the main plate 411, the lateral plates 44, the end plate 45, and the connection plate 46 may not be integrally formed.

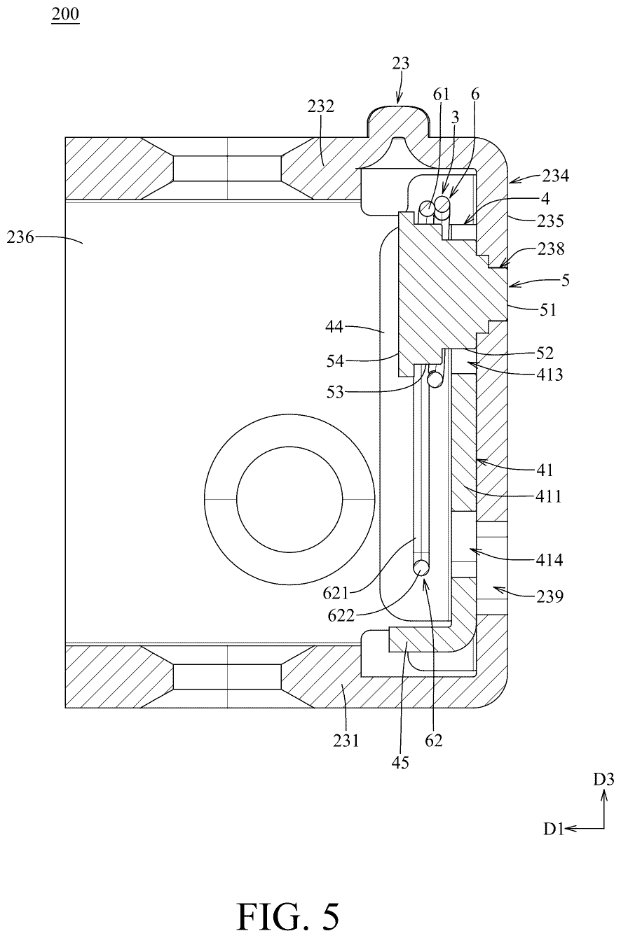

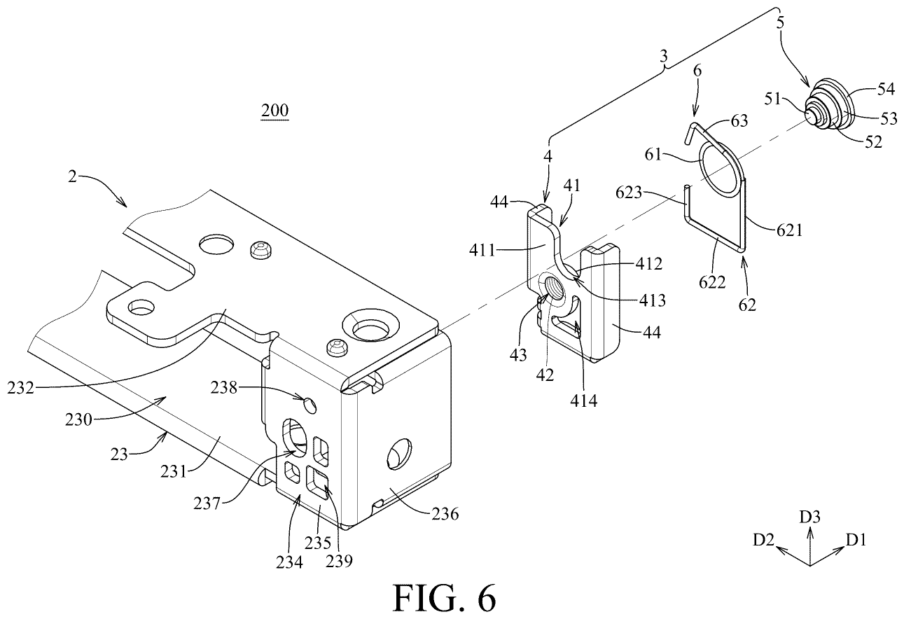

In the first embodiment, the limit member 5 is configured to be a rivet that rivets the floating bracket 41 and the rear wall 235 of the lateral frame body 234 of the frame 23. The limit member 5 has a rivet section 51, an abutment section 52, a first block section 53, and a second block section 54. The rivet section 51 extends into the open hole 238 from the front surface of the rear wall 235 to be coupled to the rear wall 235 (i.e., the limit member 5 is mounted to the open hole 238). In this embodiment, referring to FIGS. 5 and 6, the rivet section 51 is deformed in the open hole 238 so that the limit member 5 rivets the floating bracket 41 and the rear wall 235. The abutment section 52 is connected to one end of the rivet section 51. A diameter of the abutment section 52 is greater than a diameter of the rivet section 51. The abutment section 52 extends through the floating groove 413 of the floating fastener 4 to abut against the front surface of the rear wall 235. The first block section 53 is connected to one end of the abutment section 52 opposite to the rivet section 51. A diameter of the first block section 53 is greater than the diameter of the abutment section 52. The first block section 53 blocks the main plate 411 of the floating bracket 41 so that the floating bracket 41 is prevented from being separated from the chassis unit 2. The second block section 54 is connected to one end of the first block section 53 opposite to the abutment section 52. A diameter of the second block section 54 is greater than the diameter of the first block section 53.

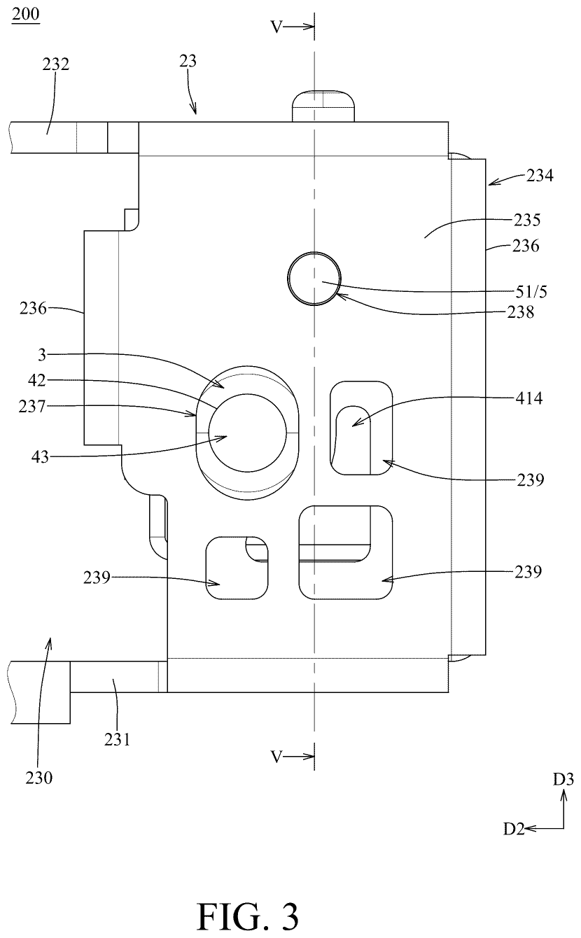

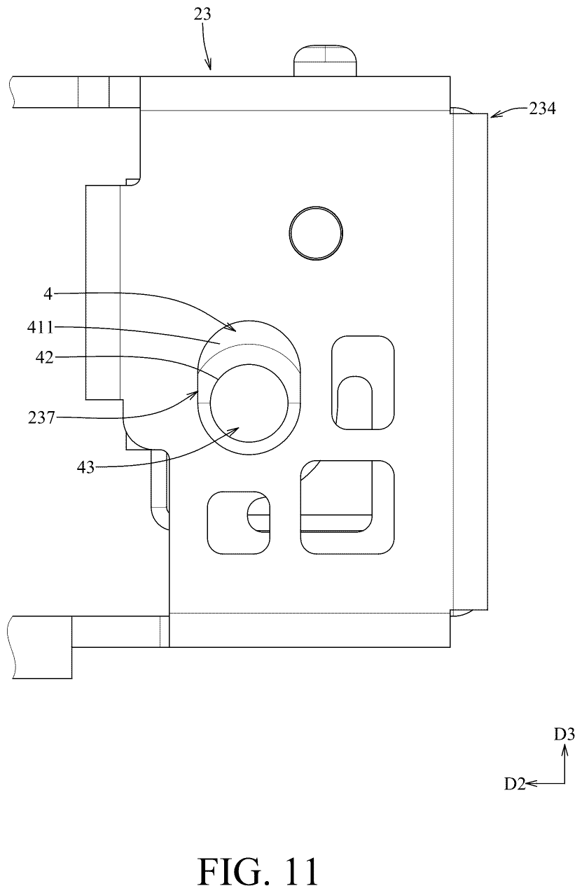

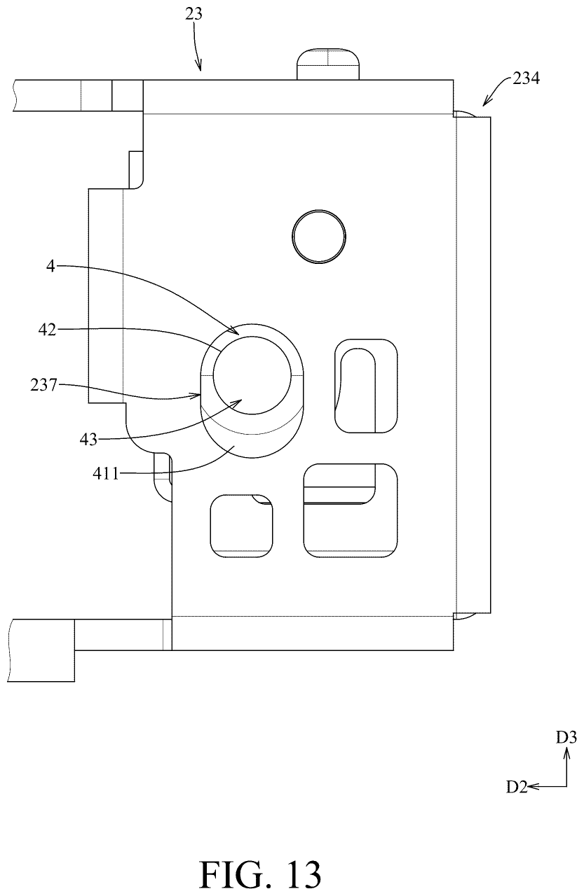

In the first embodiment, the floating fastener 4 is movable among an initial position (see FIG. 3), and a first floated position (see FIG. 11) and a second floated position (see FIG. 13) that are respectively located at two opposite sides of the initial position along the predetermined direction (D3). The first floated position is located below the initial position. The second floated position is located above the initial position. The resilient member 6 is mounted to the floating fastener 4 and resiliently urges the floating fastener 4 to move toward the initial position. The resilient member 6 is configured to be a torsion spring, and has an annular coil 61, a connection arm 62 that is connected to the annular coil 61 and that extends past a bottom end of the annular coil 61, and an abutment arm 63 that is connected to the annular coil 61, that is opposite to the connection arm 62, and that extends past a top end of the annular coil 61. The annular coil 61 is sleeved on the first block section 53 of the limit member 5, and is blocked by the second block section 54 of the limit member 5. The connection arm 62 extends through the through hole 461 of the connection plate 46 of the floating fastener 4 to be connected to the connection plate 46. The abutment arm 63 abuts against the lateral frame body 234 of the frame 23. The connection arm 62 is substantially U-shaped, and has a first arm portion 621 that is connected to the annular coil 61 and that extends downwardly from the annular coil 61 in the predetermined direction (D3), a second arm portion 622 that extends in the second transverse direction (D2) from one end of the first arm portion 621 opposite to the annular coil 61, and a third arm portion 623 that extends upwardly in the predetermined direction (D3) from one end of the second arm portion 622 opposite to the first arm portion 621. The first arm portion 621 is located between the lateral plates 44. The second arm portion 622 extends through the through hole 461 of the connection plate 46. The third arm portion 623 is located between the connection plate 46 and one of the lateral plates 44, and abuts against an inner surface of the one of the lateral plates 44. The inner surface of the one of the lateral plates 44 faces another one of the lateral plates 44. The abutment arm 63 abuts against a bottom surface of the top wall 232 of the lateral frame body 234.

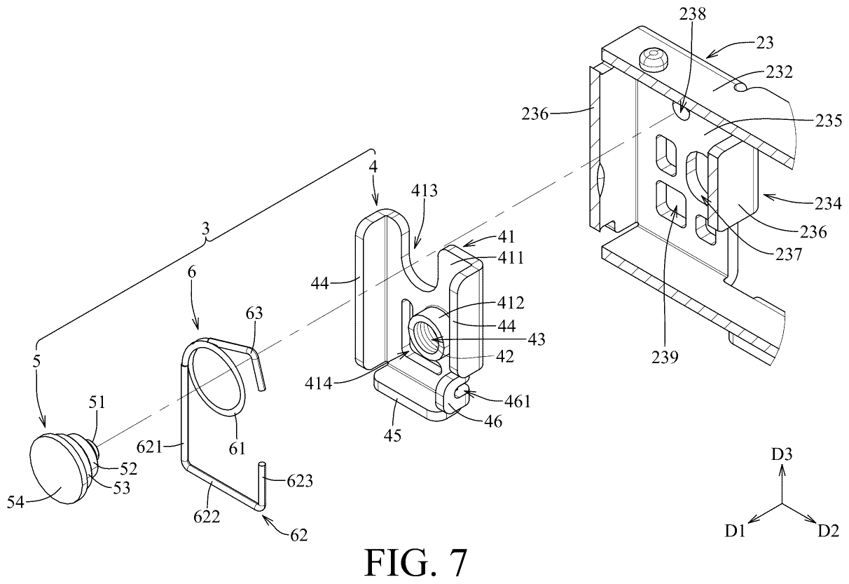

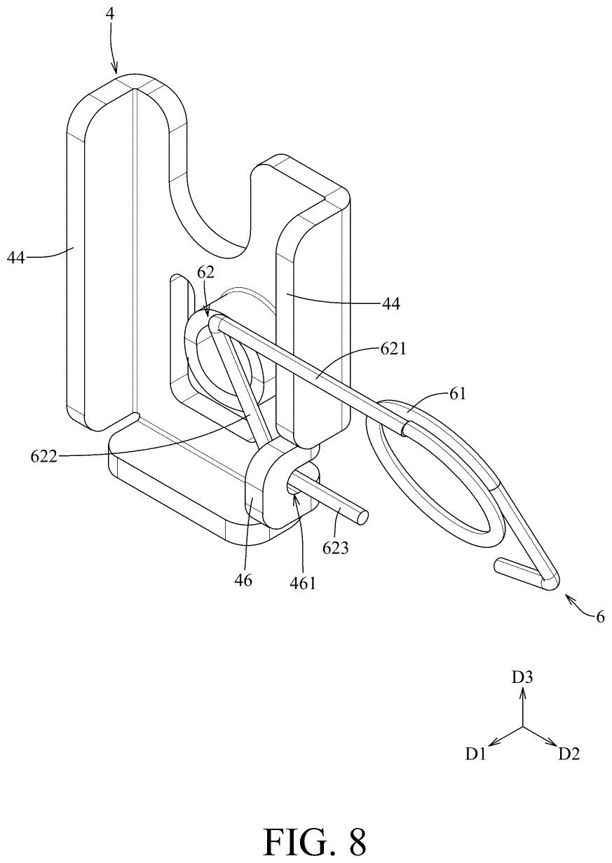

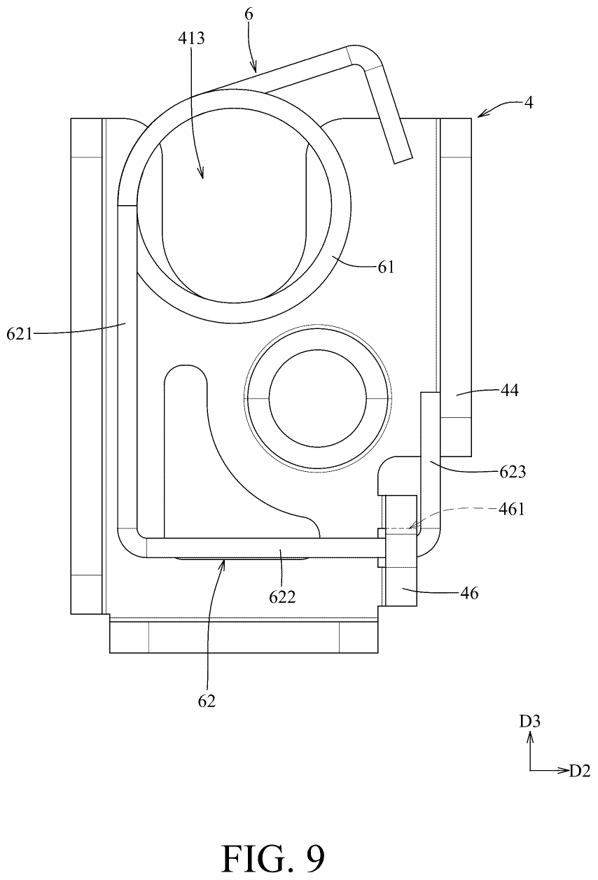

Referring to FIGS. 7 to 9, the resilient member 6 and the floating fastener 4 are assembled before assembling the floating fastener mechanism 3 and the frame 23. In order to assemble the resilient member 6 and the floating fastener 4, the resilient member 6 is prepared such that each of the first arm portion 621 and the third arm portion 623 is horizontal, and that the third arm portion 623 is located below the first arm portion 621. Then, the third arm portion 623 is moved toward the connection plate 46 and the one of the lateral plates 44, and is aligned with the through hole 461 of the connection plate 46 so that the third arm portion 623 may be moved through the through hole 461 when the resilient member 6 is moved in the second transverse direction (D2). The resilient member 6 is moved in the second transverse direction (D2) until the second arm portion 622 thereof abuts against the connection plate 46 (i.e., movement of the resilient member 6 in the second transverse direction (D2) is stopped when the second arm portion 622 abuts against the connection plate 46). Afterwards, the resilient member 6 is rotated so that the second arm portion 622 may be moved through the through hole 461, that the annular coil 61 may be aligned with the floating groove 413, and that the third arm portion 623 may be located between the connection plate 46 and the one of the lateral plates 44, and may abut against the inner surface of the one of the lateral plates 44. By virtue of the third arm portion 634 being located between the connection plate 46 and the one of the lateral plates 44, and abutting against the inner surface of the one of the lateral plates 44, the resilient member 6 is prevented from moving in the second transverse direction (D2) or a direction opposite to the second transverse direction (D3), thereby preventing the second arm portion 622 from being separated from the through hole 461 of the connection plate 46. Consequently, the resilient member 6 is stably and securely mounted to the floating fastener 4.

Referring to FIGS. 4 and 5, the assembly of the resilient member 6 and the floating fastener 4 are placed in the lateral frame body 234 of the frame 23. At this time, the main plate 411 of the floating bracket 41 abuts against the front surface of the rear wall 235, and the abutment arm 63 of the resilient member 6 abuts against the bottom surface of the top wall 232. Then, the limit member 5 is moved through the annular coil 61 of the resilient member 6 and the floating groove 413 of the floating fastener 4, and the rivet section 51 is compressed to be deformed in the open hole 238 until the abutment section 52 abuts against the front surface of the rear wall 235 so that the limit member 5 is mounted to the rear wall 235 and rivets the floating bracket 41 and the rear wall 235. At this time, the abutment section 52 extends through the floating groove 413, the first block section 53 extends through the annular coil 61 of the resilient member 6 and blocks the front surface of the main plate 411, and the second block section 54 blocks a front side of the annular coil 61 of the resilient member 6. Consequently, the floating fastener mechanism 3 and the frame 23 are assembled.

By virtue of the abutment section 52 of the limit member 5, the movement of the floating bracket 41 is limited in the predetermined direction (D3). By virtue of the first block section 53 of the limit member 5 blocking the main plate 411 of the floating bracket 41, the floating bracket 41 is prevented from rattling in the first transverse direction (D1) and from being separated from the rear wall 235 of the lateral frame body 234, thereby ensuring that the internal thread 42 and the threaded hole 43 may correspond in position to the elongated hole 237. By virtue of the second block section 54 of the limit member 5 blocking the annular coil 61 of the resilient member 6, the annular coil 61 is prevented from being separated from the first block section 53. By virtue of the rear wall 235 and the first block section 53 respectively blocking rear side and front side of the main plate 411 of the floating bracket 41, the floating fastener 4 is prevented from rattling in the first transverse direction (D1). By virtue of the lateral walls 236 respectively blocking the lateral plates 44 in the second transverse direction (D2), the floating fastener 4 is prevented from rattling in the second transverse direction (D2). Consequently, the floating fastener 4 is limited to be movable only along the predetermined direction (D3).

Referring to FIGS. 3 to 5, by virtue of the annular coil 61 being sleeved on the first block section 53 of the limit member 5, by virtue of the second arm portion 622 of the connection arm 62 extending through the through hole 461 of the connection plate 46 of the floating fastener 4, and by virtue of the abutment arm 63 abutting against the bottom surface of the top wall 232 of the frame 23, the resilient member 6 is securely mounted to the floating fastener 4, and resiliently urges the floating fastener 4 to move toward the initial position. When the floating fastener 4 is in the initial position, a center of the threaded hole 43 is aligned with a center of the elongated hole 237 of the frame 23.

Referring to FIGS. 1, 2, and 10, when the electronic component 13 is inserted to the chassis unit 2 through the insertion opening 230 and the electronic card 131 is inserted to the connector 12, the external thread member 132 extends through the elongated hole 237 and is aligned with the threaded hole 43. When the external thread member 132 enters the threaded hole 43 via rotation, an external thread 133 of the external thread member 132 is threadedly coupled to the internal thread 42 and is moved along the threaded hole 43. When the external thread member 132 is moved along the threaded hole 43 in a predetermined distance, the external thread member 132 securely and threadedly engages the internal thread 42. Therefore, the floating fastener mechanism 3 fastens the electronic component 13 to the chassis unit 2.

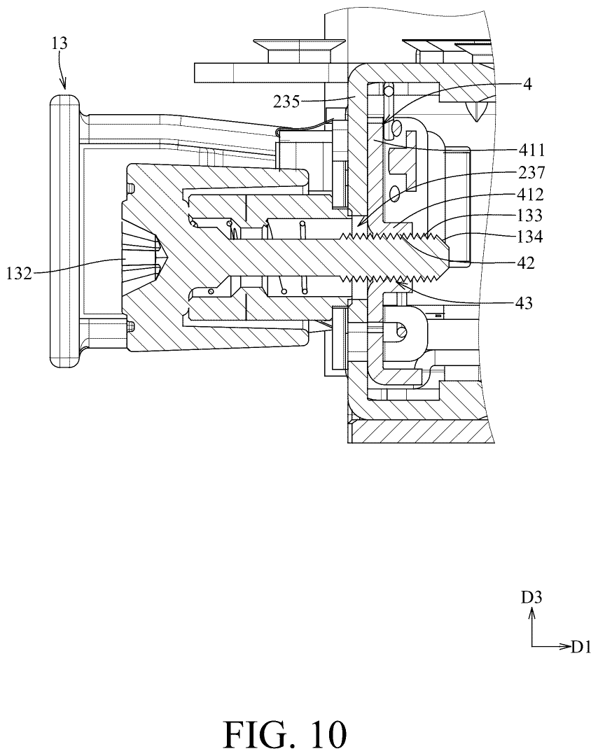

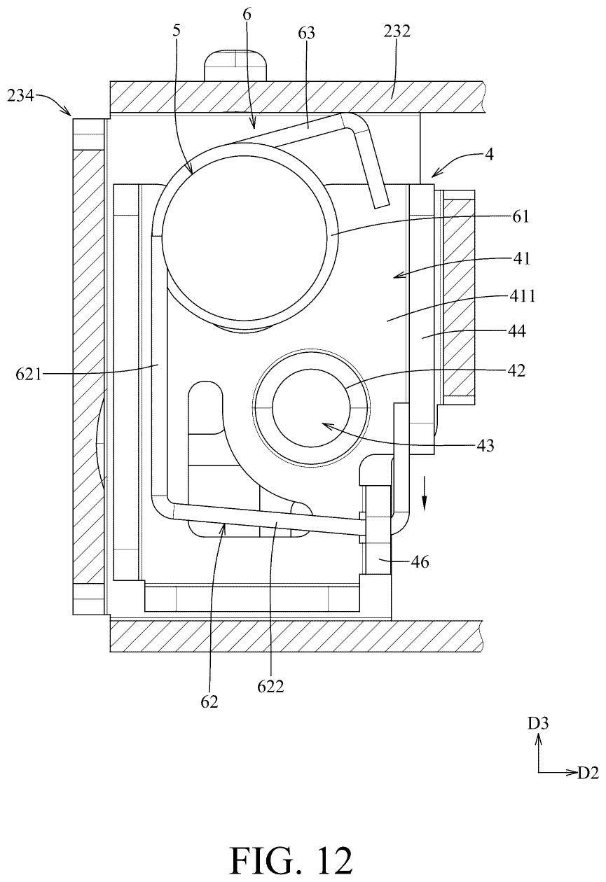

Referring to FIGS. 2 and 10 to 12, when the motherboard 11 disposed in the computer chassis 200 has, for example, a greater thickness, the height of the electronic component 13 that is inserted to the connector 12 is decreased accordingly. Therefore, when the external thread member 132 is moved toward the floating fastener 4 via rotation, a tapered surface 134 (see FIG. 10) that is connected to an end of the external thread 133 of the external thread member 132 abuts against the main plate 411 of the floating fastener 4 and pushes the main plate 411 downwardly such that the floating fastener 4 is moved downwardly along the predetermined direction (D3). When the floating fastener 4 is moved downwardly, the connection plate 46 urges the second arm portion 622 of the connection arm 62 of the resilient member 6 to move downwardly such that the second arm portion 622 is resiliently deformed and bent relative to the first arm portion 621, and stores a restoring force. When the tapered surface 134 of the external thread member 132 is separated from the main plate 411 of the floating fastener 4, the floating fastener 4 stops moving downwardly. At this time, the center of the threaded hole 43 is aligned with a center of the external thread member 132 so that the external thread member 132 may smoothly enter the threaded hole 43, and that the external thread 133 may be smoothly and threadedly coupled to the internal thread 42.

A distance in which the floating fastener 4 is moved downwardly along the predetermined direction (D3) changes according to a change in the height of the electronic component 13. In the first embodiment, a maximum distance in which the floating fastener 4 is able to move downwardly along the predetermined direction (D3) is a distance between the initial position and the first floated position (see FIG. 11). That is to say, the floating fastener 4 is able to stop at the first floated position, or any position between the initial position and the first floated position, according to the height of the electronic component 13. For example, in the first embodiment, the maximum distance (i.e., the distance between the initial position and the first floated position) may be, but not limited to, 0.5 millimeters.

When the external thread 133 of the external thread member 132 is separated from the threaded hole 43 via rotation, the second arm portion 622 of the connection arm 62 pushes the connection plate 46 back via the restoring force thereof such that the floating fastener 4 is moved upwardly back to the initial position.

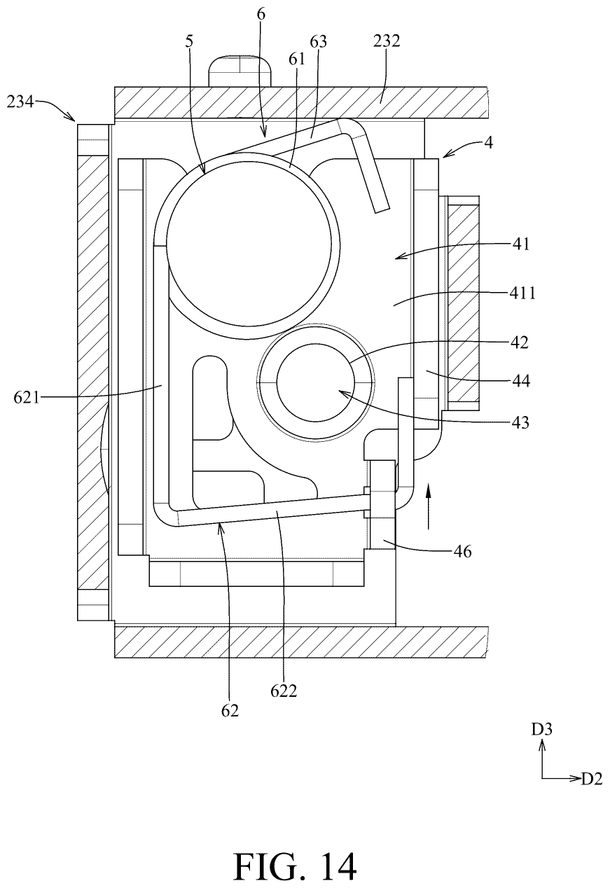

Referring to FIGS. 2, 10, 13, and 14, when the motherboard 11 disposed in the computer chassis 200 has, for example, a smaller thickness, the height of the electronic component 13 that is inserted to the connector 12 is increased accordingly. Therefore, when the external thread member 132 is moved toward the floating fastener 4 via rotation, the tapered surface 134 of the external thread member 132 abuts against the main plate 411 of the floating fastener 4 and pushes the main plate 411 upwardly such that the floating fastener 4 is moved upwardly along the predetermined direction (D3). When the floating fastener 4 is moved upwardly, the connection plate 46 urges the second arm portion 622 of the connection arm 62 of the resilient member 6 to move upwardly such that the second arm portion 622 is resiliently deformed and bent relative to the first arm portion 621, and stores the restoring force. At this time, the abutment arm 63 is pressed by the top wall 232, is resiliently deformed and bent relative to the annular coil 61, and stores a restoring force. When the tapered surface 134 of the external thread member 132 is separated from the main plate 411 of the floating fastener 4, the floating fastener 4 stops moving upwardly. At this time, the center of the threaded hole 43 is aligned with the center of the external thread member 132 so that the external thread member 132 may smoothly enter the threaded hole 43, and that the external thread 133 may be smoothly and threadedly coupled to the internal thread 42.

A distance in which the floating fastener 4 is moved upwardly along the predetermined direction (D3) changes according to a change in the height of the electronic component 13. In the first embodiment, a maximum distance in which the floating fastener 4 is able to move upwardly along the predetermined direction (D3) is a distance between the initial position and the second floated position (see FIG. 13). That is to say, the floating fastener 4 is able to stop at the second floated position, or any position between the initial position and the second floated position, according to the height of the electronic component 13. For example, in the first embodiment, the maximum distance (i.e., the distance between the initial position and the second floated position) may be, but not limited to, 0.5 millimeters.

When the external thread 133 of the external thread member 132 is separated from the threaded hole 43 via rotation, the second arm portion 622 of the connection arm 62 pushes the connection plate 46 back via the restoring force thereof, and the abutment arm 63 urges the annular coil 61 and the connection arm 62 to push the connection plate 46 back via the restoring force thereof such that the floating fastener 4 is moved downwardly back to the initial position.

It is noted that, the computer chassis 200 may have different modifications according to actual requirements. In one of the modifications, the floating fastener 4 is movable between the initial position and the first floated position below the initial position. In another one of the modifications, the floating fastener 4 is movable between the initial position and the second floated position above the initial position.

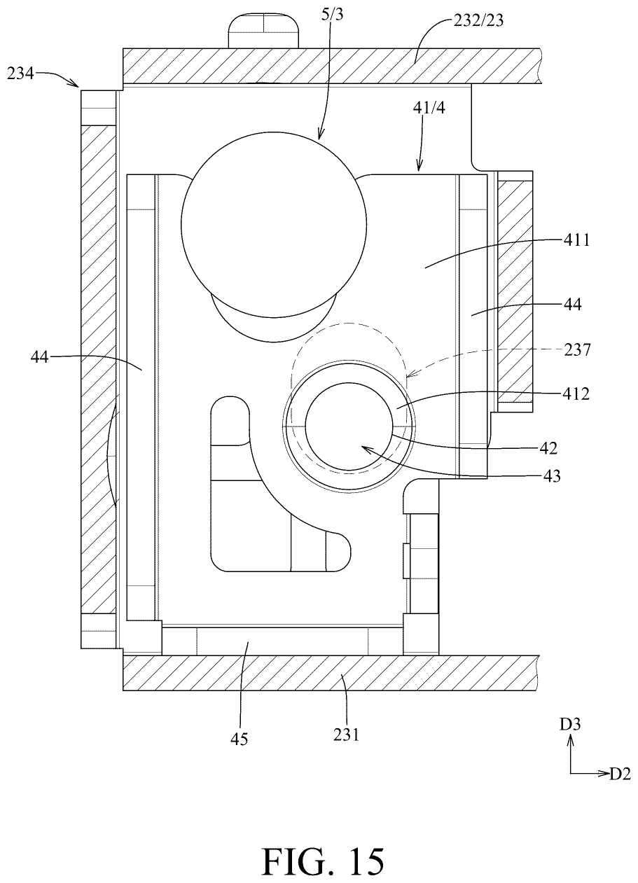

Referring to FIG. 15, a second embodiment of the computer chassis 200 according to the disclosure is generally similar to the first embodiment, but includes differences lying in the floating fastener mechanism 3.

In the second embodiment, the floating fastener mechanism 3 does not include the resilient member 6 as shown in FIG. 4. When the floating fastener 4 is in the initial position, the end plate 45 abuts against the base wall 231 of the frame 23, and the center of the threaded hole 43 is located below the center of the elongated hole 237. Thus, compared with the floating fastener mechanism 3 in the first embodiment, the floating fastener mechanism 3 in the second embodiment may include fewer components, thereby reducing manufacturing cost.

In summary, by virtue of the abovementioned design of the floating fastener mechanism 3 in any one of the first and second embodiments of the computer chassis 200, even when the height of the electronic component 13 is offset according to the different thickness of the motherboard 11 that is disposed in the chassis unit 2, the floating fastener mechanism 3 may stably fasten the electronic component 13 to the motherboard 11. Therefore, the purpose of the present disclosure is indeed achieved.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A floating fastener mechanism adapted to be disposed on a chassis unit of a computer chassis and adapted to fasten an electronic component, the floating fastener mechanism comprising:
a floating fastener having a floating bracket that is adapted to be disposed on the chassis unit and that is operable to move relative to the chassis unit in a predetermined direction, and an internal thread that is disposed on the floating bracket and that is adapted for an external thread member of the electronic component to threadedly engage therewith; and
a limit member adapted for limiting movement of the floating bracket relative to the chassis unit.

2. The floating fastener mechanism as claimed in claim 1, wherein the floating bracket has a main plate that is adapted for abutting against the chassis unit, and an annular protrusion that protrudes from the main plate, the internal thread being formed on the main plate and the annular protrusion, and cooperating with the main plate and the annular protrusion to define a threaded hole that is adapted for the external thread member of the electronic component to insert therein.

3. The floating fastener mechanism as claimed in claim 1, wherein the floating bracket is formed with a floating groove that is elongated in the predetermined direction, the limit member extending through the floating groove and movably engaging the floating groove so that the floating groove is movable relative to the chassis unit in the predetermined direction, the limit member having a block section that blocks the floating bracket so that the floating bracket is prevented from being separated from the chassis unit.

4. The floating fastener mechanism as claimed in claim 1, wherein the floating fastener further has two lateral plates that are respectively connected to two opposite sides of the floating bracket, and that are spaced apart from each other in a transverse direction transverse to the predetermined direction, each of the lateral plates being elongated in the predetermined direction and adapted to be blocked by the chassis unit in the transverse direction.

5. The floating fastener mechanism as claimed in claim 1, wherein the floating fastener further has an end plate that is connected to the floating bracket.

6. The floating fastener mechanism as claimed in claim 1, wherein the floating bracket is formed with a vent hole.

7. The floating fastener mechanism as claimed in claim 1, wherein the limit member is configured to be a rivet that rivets the floating bracket and the chassis unit.

8. The floating fastener mechanism as claimed in claim 1, wherein the floating fastener is movable between an initial position and a floated position, the floating fastener mechanism further comprising a resilient member that is mounted to the floating fastener and that resiliently urges the floating fastener to move toward the initial position.

9. The floating fastener mechanism as claimed in claim 1, wherein the floating fastener is movable among an initial position, and a first floated position and a second floated position that are respectively located at two opposite sides of the initial position along the predetermined direction, the floating fastener mechanism further comprising a resilient member that is mounted to the floating fastener and that resiliently urges the floating fastener to move toward the initial position.

10. The floating fastener mechanism as claimed in claim 9, wherein the resilient member is configured to be a torsion spring, and has an annular coil that is sleeved on the limit member, a connection arm that is connected to the annular coil, and an abutment arm that is connected to the annular coil and that is opposite to the connection arm, the connection arm being connected to the floating fastener, the abutment arm being adapted for abutting against the chassis unit.

11. The floating fastener mechanism as claimed in claim 10, wherein the floating fastener further has a connection plate that is connected to the floating bracket, the connection plate being formed with a through hole, the connection arm of the resilient member having a first arm portion that is connected to the annular coil and that extends in the predetermined direction, and a second arm portion that extends in a transverse direction from one end of the first arm portion opposite to the annular coil and that extends through the through hole, the transverse direction being transverse to the predetermined direction.

12. The floating fastener mechanism as claimed in claim 11, wherein the floating fastener further has two lateral plates that are respectively connected to two opposite sides of the floating bracket, and that are spaced apart from each other in the transverse direction, each of the lateral plates being elongated in the predetermined direction and adapted to be blocked by the chassis unit in the transverse direction, the connection arm of the resilient member further having a third arm portion that extends in the predetermined direction from one end of the second arm portion opposite to the first arm portion, the third arm portion being located between the connection plate and one of the lateral plates, and abutting against the one of the lateral plates.

13. The floating fastener mechanism as claimed in claim 10, wherein the limit member is configured to be a rivet that rivets the floating bracket and the chassis unit, the limit member having a rivet section, an abutment section, a first block section, and a second block section, the rivet section being adapted to be coupled to the chassis unit, the abutment section being connected to one end of the rivet section and adapted for abutting against the chassis unit, a diameter of the abutment section being greater than a diameter of the rivet section, the first block section being connected to one end of the abutment section opposite to the rivet section, a diameter of the first block section being greater than the diameter of the abutment section, the second block section being connected to one end of the first block section opposite to the abutment section, a diameter of the second block section being greater than the diameter of the first block section, the floating bracket being formed with a floating groove that is elongated in the predetermined direction, the abutment section of the limit member extending through the floating groove, the first block section of the limit member blocking the floating bracket, the annular coil of the resilient member being sleeved on the first block section of the limit member and being blocked by the second block section of the limit member.

14. A computer chassis adapted for an electronic component to be inserted thereto, the computer chassis comprising:
a chassis unit; and
the floating fastener mechanism as claimed in claim 1, the chassis unit being formed with an elongated hole that is elongated in the predetermined direction, that corresponds in position to the internal thread of the floating fastener, and that is adapted for an external thread member of the electronic component to extend therethrough to threadedly engage the internal thread.

15. The computer chassis as claimed in claim 14, wherein the chassis unit is further formed with an open hole, the limit member being mounted to the open hole.

16. The computer chassis as claimed in claim 14, wherein the floating fastener is movable among an initial position, and a first floated position and a second floated position that are respectively located at two opposite sides of the initial position along the predetermined direction, the floating fastener mechanism further comprising a resilient member that is mounted to the floating fastener and that resiliently urges the floating fastener to move toward the initial position.

17. The computer chassis as claimed in claim 16, wherein the resilient member is configured to be a torsion spring, and has an annular coil that is sleeved on the limit member, a connection arm that is connected to the annular coil, and an abutment arm that is connected to the annular coil and that is opposite to the connection arm, the connection arm being connected to the floating fastener, the abutment arm abutting against the chassis unit.

18. The computer chassis as claimed in claim 17, wherein the floating fastener further has a connection plate that is connected to the floating bracket, the connection plate being formed with a through hole, the connection arm of the resilient member having a first arm portion that is connected to the annular coil and that extends in the predetermined direction, and a second arm portion that extends in a transverse direction from one end of the first arm portion opposite to the annular coil and that extends through the through hole, the transverse direction being transverse to the predetermined direction.

19. The computer chassis as claimed in claim 18, wherein the floating fastener further has two lateral plates that are respectively connected to two opposite sides of the floating bracket, and that are spaced apart from each other in the transverse direction, each of the lateral plates being elongated in the predetermined direction and being blocked by the chassis unit in the transverse direction, the connection arm of the resilient member further having a third arm portion that extends in the predetermined direction from one end of the second arm portion opposite to the first arm portion, the third arm portion being located between the connection plate and one of the lateral plates, and abutting against the one of the lateral plates.

20. The computer chassis as claimed in claim 17, wherein the chassis unit is further formed with an open hole, the limit member being configured to be a rivet that rivets the floating bracket and the chassis unit, the limit member having a rivet section, an abutment section, a first block section, and a second block section, the rivet section extending into the open hole to be coupled to the chassis unit, the abutment section being connected to one end of the rivet section and abutting against the chassis unit, a diameter of the abutment section being greater than a diameter of the rivet section, the first block section being connected to one end of the abutment section opposite to the rivet section, a diameter of the first block section being greater than the diameter of the abutment section, the second block section being connected to one end of the first block section opposite to the abutment section, a diameter of the second block section being greater than the diameter of the first block section, the floating bracket being formed with a floating groove that is elongated in the predetermined direction, the abutment section of the limit member extending through the floating groove, the first block section of the limit member blocking the floating bracket, the annular coil of the resilient member being sleeved on the first block section of the limit member and being blocked by the second block section of the limit member.
